(19) United States
(12) Patent Application Publication
(10) Pub. No.: US 2024/0021234 A1
(43) Pub. Date: Jan. 18, 2024

(54) MEMORY DEVICE PERFORMING REFRESH OPERATION

(71) Applicant: SAMSUNG ELECTRONICS CO., LTD., Suwon-si (KR)

(72) Inventor: Kwangsook NOH, Suwon-si (KR)

(21) Appl. No.: 18/156,126

(22) Filed: Jan. 18, 2023

(30) Foreign Application Priority Data
Jul. 13, 2022 (KR) 10-2022-0086047

(51) Int. Cl. G11C 11/406; G11C 11/408

(52) U.S. Cl. CPC G11C 11/40622; G11C 11/40615; G11C 11/4087

(57) ABSTRACT

Disclosed is a memory device which includes a memory bank including a plurality of memory cells, and control logic controlling a data input/output operation for the plurality of memory cells. The control logic partially measures a refresh count, which is associated with the number of times of occurrence of at least one event causing a leakage current in the plurality of memory cells, with respect to the memory bank, and partially performs a refresh operation on the memory bank based on the refresh count.

### CROSS-REFERENCE TO RELATED APPLICATIONS

This application claims priority under 35 U.S.C. § 119 to Korean Patent Application No. 10-2022-0086047 filed on Jul. 13, 2022, in the Korean Intellectual Property Office, the disclosures of which are incorporated by reference herein in their entireties.

### BACKGROUND

Embodiments of the present invention described herein relate to a memory device, and more particularly, relate to a memory device performing a refresh operation in consideration of various events causing a leakage current in a memory cell.

A semiconductor memory device may be classified as a volatile semiconductor memory device or a non-volatile semiconductor memory device. The volatile semiconductor memory device is fast in read and write speeds but loses data stored therein when a power is turned off. In contrast, even though a power is turned off, the non-volatile semiconductor memory device retains information (e.g., data) stored therein. Therefore, the non-volatile semiconductor memory device is used to store information (e.g., data) that has to be retained regardless of whether a power is supplied.

In general, a memory cell of the volatile semiconductor memory device (e.g., a dynamic random access memory (DRAM)) may include one NMOS transistor playing a role of a switch and one capacitor (e.g., cell capacitor) storing data (e.g., charges). Binary information (e.g., data) “1” or “0” may be stored depending on whether a certain amount of charges are present in the capacitor of the memory cell, that is, whether a terminal voltage of the capacitor is high or low. A write operation may be performed by applying a voltage corresponding to binary information (e.g., data) to the memory cell, and the binary information (e.g., data) of the memory cell may be read by detecting a voltage change according to whether a certain amount of charges are present in the capacitor. The binary data are retained because of the charges accumulated in the capacitor. This means that there is no power consumption in principle for retaining the stored binary data. However, due to a leakage current in the PN junction of the NMOS transistor caused by various events, the initial amount of charges stored in the capacitor may decrease; in this case, the stored binary data may be lost by the leakage current. Accordingly, before the stored binary data are lost, there may be performed a refresh operation in which the stored data of the memory cell are read and the capacitor in the memory cell is recharged with the initial charge amount based on the read data. Thus, the stored binary data in the memory cell may be maintained by periodically repeating the refresh operation. However, in the case where the refresh operation is excessively repeated, the overall performance of the volatile semiconductor memory device deteriorates; in contrast, in the case where a time period between the refresh operations is excessively elongated, there is a risk of data loss.

### SUMMARY

Embodiments of the present invention provide a memory device performing a refresh operation in consideration of various events causing a leakage current in a memory cell.

According to an embodiment of the present invention, a memory device comprising: a memory bank including a plurality of memory cells; and a control logic configured to control a data input/output operation for the plurality of memory cells, wherein the control logic is configured to: partially measure a refresh count, which is associated with a number of occurrences of an event causing a leakage current in the plurality of memory cells; and partially perform a refresh operation on the memory bank based on the refresh count.

According to another embodiment of the present invention, a memory device comprising: a memory bank including a plurality of memory blocks that includes a plurality of memory cells; and a control logic configured to control a data input/output operation for the plurality of memory cells, wherein the control logic is configured to: measure a refresh count that is calculated based on a first count and a second count; and perform a refresh operation for a memory block from among the plurality of memory blocks, based on the refresh count.

According to another embodiment of the present invention, a memory device comprising: a memory bank including a plurality of memory blocks that includes a plurality of memory cells; and a control logic configured to control a data input/output operation for the plurality of memory cells, wherein the control logic is configured to: generate a block signal for selecting a first memory block from among the plurality of memory blocks based on an active request and a row address received from a controller; when the active request and the block signal are activated, increase a first count for the first memory block, or when an oscillation signal to be periodically generated is activated, increase a second count for each of the plurality of memory blocks; and perform a refresh operation on the first memory block, based on a refresh count that is calculated based on the first and second counts.

### BRIEF DESCRIPTION OF THE FIGURES

The above and other objects and features of the present invention will be more clearly understood from the following detailed description taken in conjunction with the accompanying drawings in which:

FIG. 1 is a block diagram illustrating a memory system according to an embodiment;

FIG. 2 is a block diagram illustrating a block decoder and an oscillator included in a control logic of FIG. 1;

FIG. 3 is a block diagram illustrating components for a refresh operation of a memory device of FIG. 1;

FIG. 4 is a diagram illustrating an example of a count manager of FIG. 3;

FIG. 5 is a diagram illustrating another example of a count manager of FIG. 3;

FIG. 6 is a diagram illustrating another example of a count manager of FIG. 3;

FIG. 7 is a graph illustrating a leakage current of a memory cell according to a temperature of a memory device according to an embodiment; and

FIG. 8 is a diagram illustrating a refresh operation of a memory device of FIG. 3.

### DETAILED DESCRIPTION

Below, embodiments of the present invention will be described in detail and clearly to such an extent that an ordinary one in the art easily implements the invention.

Also, below, a dynamic random access memory (DRAM) may be used as an example of a semiconductor memory device for describing features and functions of the present invention. However, one skilled in the art may easily understand other merits and performance of the invention depending on the content disclosed in the specification. The present invention may be implemented or applied through other embodiments. In addition, the detailed description may be changed or modified depending on view points and applications without departing from the claims, the scope, and any other purposes of the present invention.

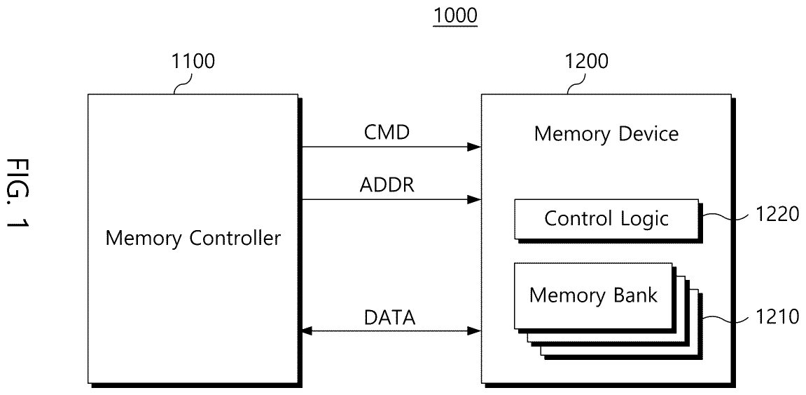

FIG. 1 is a block diagram illustrating a memory system according to an embodiment. Referring to FIG. 1, a memory system 1000 of the present invention may include a memory controller 1100 and a memory device 1200.

According to an embodiment, the memory controller 1100 may perform an access operation to write data in the memory device 1200 or to read data stored in the memory device 1200. For example, the memory controller 1100 may generate a command CMD and an address ADDR for writing data in the memory device 1200 or reading data stored in the memory device 1200. The memory controller 1100 may be a system on chip (SoC) such as an application processor (AP), a central processing unit (CPU), a digital signal processor (DSP), or a graphics processing unit (GPU), but not limited thereto.

According to an embodiment, the memory controller 1100 may control the overall operation of the memory device 1200 by providing various kinds of signals to the memory device 1200. For example, the memory controller 1100 may control a memory access operation of the memory device 1200, such as a read operation or a write operation. The memory controller 1100 may provide the memory device 1200 with the command CMD and the address ADDR for the purpose of writing data “DATA” in the memory device 1200 or reading the data “DATA” stored in the memory device 1200.

According to an embodiment, the memory controller 1100 may generate various kinds of commands CMD for controlling the memory device 1200. For example, to read or write the data “DATA”, the memory controller 1100 may generate a bank request corresponding to a bank operation for state switching of a memory bank included in memory banks 1210. As an example, the bank request may include an active request for setting a memory bank included in the memory banks 1210 to the active state. The memory device 1200 may activate a memory row (e.g., word line) in which a memory cell array may be arranged. The memory row may be included in the memory bank and activated in response to the active request. The bank request may include a precharge request for switching the state of the memory bank from the active state to the standby state after the data “DATA” are completely read or written. Also, the memory controller 1100 may generate an input/output (I/O) request (e.g., a CAS request) that allows the memory device 1200 to perform the read operation or the write operation on the data “DATA”. As an example, the I/O request may include a read request for reading the data “DATA” from the activated memory bank. The I/O request may include a write request for writing the data “DATA” in the activated memory bank. Also, the memory controller 1100 may generate a refresh command for controlling a refresh operation of the memory bank. However, the command kinds described above are provided as an example, and any other kinds of commands CMD may be implemented.

According to an embodiment, the memory device 1200 may output the read-requested data “DATA” requested by the memory controller 1100 to the memory controller 1100 or may store the write-requested data “DATA” requested by the memory controller 1100 in memory cells. The memory device 1200 may input/output the data “DATA” based on the command CMD and the address ADDR. The memory device 1200 may include the memory banks 1210 and control logic 1220.

Herein, the memory device 1200 may be a volatile memory device such as a dynamic random access memory (DRAM), a synchronous DRAM (SDRAM), a double data rate (DDR) DRAM, a DDR SDRAM, a low-power double data rate (LPDDR) SDRAM, a graphics double data rate (GDDR) SDRAM, a Rambus DRAM (RDRAM), or a static random access memory (SRAM). Alternatively, the memory device 1200 may be implemented with a memory device such as a resistive random access memory (RRAM), a phase-change random access memory (PRAM), a magnetic random access memory (MRAM), a ferroelectric random access memory (FRAM), a spin transfer torque random access memory (STT-RAM). In the specification, the advantages of the present invention will be described based on a DRAM, but the embodiments of the present invention are not limited thereto.

According to an embodiment, each of the memory banks 1210 may include a memory cell array and a bank unit, a row decoder, a column decoder, a sense amplifier, a write driver, etc., corresponding thereto. The memory banks 1210 may store write-requested data “DATA” in the memory cell array of the memory device 1200 through the write driver and may read read-requested data “DATA” by using the sense amplifier. In addition, components for the refresh operation for storing and retaining data “DATA” in the memory cell array and/or address-based select circuits may be further provided.

According to an embodiment, the control logic 1220 may be provided with the command CMD and the address ADDR from the memory controller 1100. The control logic 1220 may control the write, read, or delete (or erase) operation of the memory device 1200 by using the command CMD and the address ADDR.

According to an embodiment, the memory device 1200 may (partially) perform a refresh operation for a part (e.g., a memory block) of the memory banks 1210. For example, one of the memory banks 1210 may be divided into a plurality of memory blocks. A memory block may include a memory row group (e.g., a plurality of word lines) identified by a sense amplifier. Alternatively, a memory block may include a memory row group identified by a plurality of sense amplifiers.

According to an embodiment, the memory device 1200 may (partially) measure a refresh count, which corresponds to the number of times of occurrence of an event causing a leakage current in a plurality of memory cells included in the memory banks 1210, for each memory block and may perform the refresh operation for each memory block based on the measured refresh count. For example, the event causing the leakage current may include receiving the active command activating a memory row in a memory block (or a part of a memory bank). The event causing the leakage current may include the event that a memory block (or a part of a memory bank) is maintained in the active state during a specified time or more. The event causing the leakage current may include the event that an oscillation signal is generated by the control logic 1220 with a specified period. Meanwhile, the memory device 1200 may apply different weights to the above events causing the leakage current and may increase the refresh count.

The memory device 1200 of the present invention may divide a memory bank into memory blocks and may obtain the respective refresh count for each memory block. The refresh count may include a count by the number of times of access to a memory block (or a count corresponding to a dynamic leakage current of a memory cell, which is proportional to the number of times of access to an adjacent memory cell) and a count increasing periodically in consideration of a characteristic of the memory cell (or a count corresponding a static leakage current according to the characteristic of the memory cell). The memory device 1200 may perform the refresh operation based on the above refresh count. The memory device 1200 may perform the refresh operation on a memory block whose refresh count reaches a refresh reference value. Also, the memory device 1200 may perform the refresh operation in consideration of both the dynamic leakage current and the static leakage current. Also, the performance deterioration of the memory device 1200 may be reduced (or prevented) by preventing the refresh operation for the static leakage current and the refresh operation for the dynamic leakage current from overlapping each other.

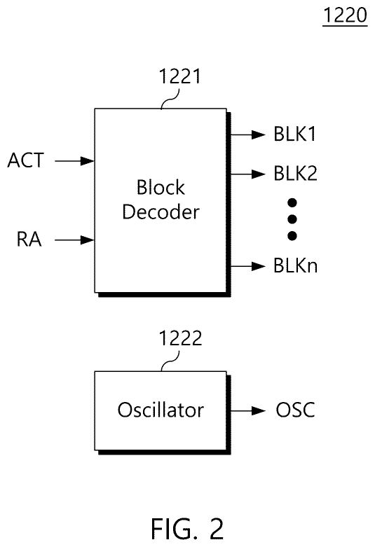

FIG. 2 is a block diagram illustrating a block decoder and an oscillator included in control logic of FIG. 1. Referring to FIG. 2, the control logic 1220 may include a block decoder 1221 and an oscillator 1222.

According to an embodiment, the block decoder 1221 may receive an active request ACT and a row address RA. For example, the active request ACT may be included in the command CMD received from the memory controller 1100. The active request ACT refers to a command for switching a state of a memory row included in one memory bank selected from the memory banks 1210 to the active state for the purpose of inputting/outputting data.

The row address RA may be included in the address ADDR received from the memory controller 1100. The row address RA may indicate a location of a memory row corresponding to the received active request ACT. The block decoder 1221 may generate block signals BLK1, BLK2, . . . , BLKn based on the active request ACT and the row address RA.

According to an embodiment, the oscillator 1222 may generate an oscillation signal OSC having information of a specified period. For example, the specified period of the oscillation signal OSC may be determined depending on a refresh period that is based on a characteristic of a memory cell included in the memory banks 1210. As the temperature of the memory device 1200 increases, the specified period of the oscillation signal OSC may decrease. As the temperature of the memory device 1200 decreases, the specified period of the oscillation signal OSC may increase.

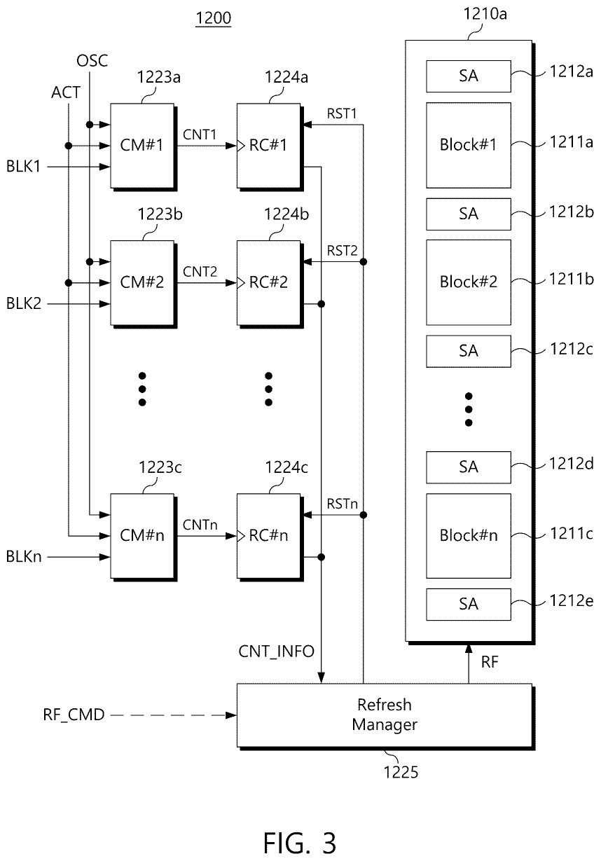

FIG. 3 is a block diagram illustrating components for a refresh operation of a memory device of FIG. 1. Referring to FIGS. 1 to 3, the memory device 1200 may include sub-components of the control logic 1220 for the refresh operation of memory cells included in the memory banks 1210.

According to an embodiment, one memory bank 1210a may be divided into a plurality of memory blocks 1211a, 1211b, . . . , and 1211c. For example, the plurality of memory blocks 1211a, 1211b, . . . , 1211c may be distinguished from each other by a plurality of sense amplifiers 1212a, 1212b, 1212c, . . . , 1212d, and 1212e. As an example, the first memory block 1211a may receive/output data through the sense amplifiers 1212a and 1212b. The second memory block 1211b may receive/output data through the sense amplifiers 1212b and 1212c. The n-th memory block 1211c may receive/output data through the sense amplifiers 1212d and 1212e. As another example, each of the plurality of memory blocks 1211a, 1211b, . . . , and 1211c may receive/output data through one sense amplifier disposed on one side thereof. As another example, at least two of the plurality of memory blocks 1211a, 1211b, . . . , and 1211c may constitute one refresh block (e.g., the memory blocks constituting the refresh block may receive/output data through one sense amplifier.).

According to an embodiment, the control logic 1220 may include a count manager and a refresh counter corresponding to each of the plurality of memory blocks 1211a, 1211b, . . . , and 1211c. For example, a first count manager 1223a may generate a first count signal CNT1 based on the active request ACT, a first block signal BLK1, and the oscillation signal OSC. When an access to the first memory block 1211a is made based on the active request ACT and the first block signal BLK1, the first count manager 1223a may output the first count signal CNT1 that increases a refresh count of a first refresh counter 1224a. Also, the first count manager 1223a may periodically output the first count signal CNT1, which increases the refresh count of the first refresh counter 1224a, based on the oscillation signal OSC. The first refresh counter 1224a may store the refresh count corresponding to the first memory block 1211a. The first refresh counter 1224a may increase the refresh count corresponding to the first memory block 1211a as much as one, based on the first count signal CNT1.

Likewise, a second count manager 1223b may generate a second count signal CNT2 based on the active request ACT, a second block signal BLK2, and the oscillation signal OSC. A second refresh counter 1224b may increase the refresh count corresponding to the second memory block 1211b based on the second count signal CNT2. The n-th count manager 1223c may generate an n-th count signal CNTn based on the active request ACT, an n-th block signal BLKn, and the oscillation signal OSC. An n-th refresh counter 1224c may increase the refresh count corresponding to the n-th memory block 1211c based on the n-th count signal CNTn.

According to an embodiment, the control logic 1220 may further include a refresh manager 1225. For example, the refresh manager 1225 may perform the refresh operation on the memory bank 1210a for each memory block therein. The refresh manager 1225 may receive count information CNT_INFO from the refresh counters 1224a, 1224b, and 1224c. The count information CNT_INFO may include a refresh count value of each of the refresh counters 1224a, 1224b, . . . , and 1224c. The refresh manager 1225 may send a refresh signal RF to the memory bank 1210a such that the refresh operation is performed on a memory block whose refresh count value reaches a specified reference value.

According to an embodiment, the refresh manager 1225 may send reset signals to the refresh counters 1224a, 1224b, . . . , and 1224c, respectively. For example, the refresh manager 1225 may send a reset signal (e.g., RST1, RST2, . . . , and RSTn) to a refresh counter that corresponds to a memory block on which the refresh operation is performed as the refresh count value reaches the specified reference value. The refresh counters 1224a, 1224b, . . . , 1224c may respectively initialize the refresh counts to “0” based on the corresponding reset signals RST1, RST2, . . . , and RSTn.

According to an embodiment, the refresh manager 1225 may receive a refresh command RF_CMD. For example, the refresh command RF_CMD may be received from the memory controller 1100 or may be internally generated by the control logic 1220. As an example, when the refresh command RF_CMD is received, the refresh manager 1225 may receive the count information CNT_INFO from the refresh counters 1224a, 1224b, . . . , and 1224c and may compare the count information CNT_INFO with the refresh reference value. The refresh manager 1225 may send the refresh signal RF to the memory bank 1210a based on the refresh command RF_CMD.

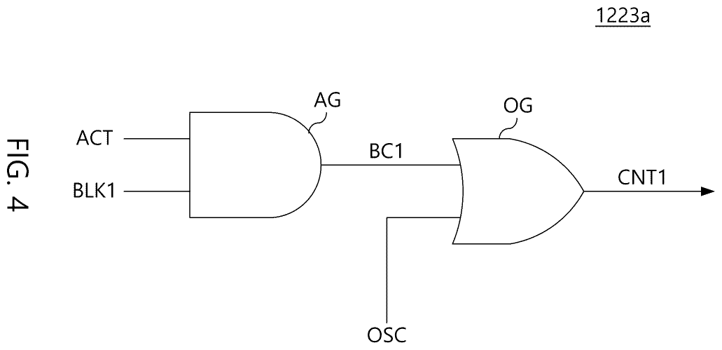

FIG. 4 is a diagram illustrating an example of a count manager of FIG. 3. Referring to FIGS. 3 and 4, the first count manager 1223a may include an AND gate AG and an OR gate OG. Likewise, the remaining count managers 1223b, . . . , and 1223c may include the same configuration as the first count manager 1223a. Below, the first count manager 1223a will be described as an example.

According to an embodiment, the AND gate AG may output a first block count signal BC1 by performing an AND operation on the active request ACT and the first block signal BLK1. The OR gate OG may output the first count signal CNT1 by performing an OR operation on the first block count signal BC1 and the oscillation signal OSC. When the access to the first memory block 1211a is made, the first count signal CNT1 may increase the refresh count of the first refresh counter 1224a. Also, the first count signal CNT1 may increase the refresh count of the first refresh counter 1224a periodically depending on the oscillation signal OSC. That is, the first refresh counter 1224a may increase the refresh count in consideration of both the event that a leakage current occurs due to the access to the first memory block 1211a (or the leakage current occurrence event associated with the number of times of access to the first memory block 1211a) and the event that a leakage current occurs due to a characteristic of a memory cell regardless of whether the access to the first memory block 1211a is made. Meanwhile, because the refresh manager 1225 performs the refresh operation of the first memory block 1211a based on the refresh count stored in the first refresh counter 1224a, the refresh operation according to the access to the first memory block 1211a (or the refresh operation associated with the number of times of access to the first memory block 1211a) and the refresh operation according to a characteristic of a memory cell may be prevented from overlapping each other.

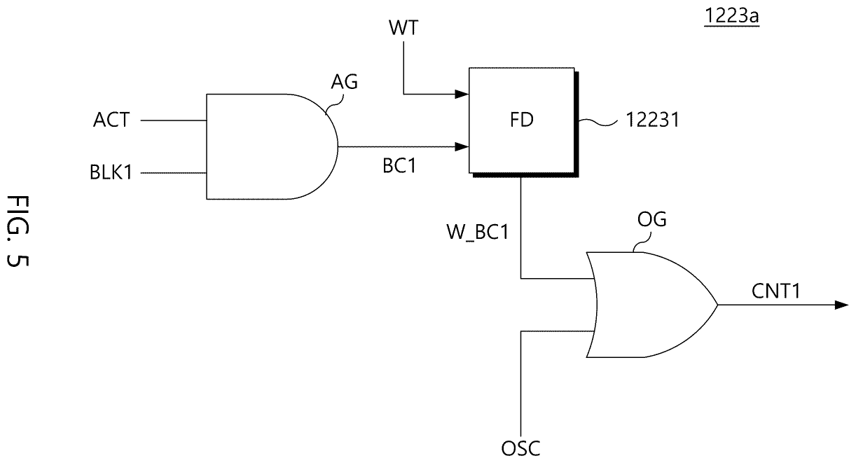

FIG. 5 is a diagram illustrating another example of a count manager of FIG. 3. Referring to FIGS. 3 and 5, the first count manager 1223a may include an AND gate AG, a frequency divider 12231, and an OR gate OG. Likewise, the remaining count managers 1223b, . . . , and 1223c may include the same configuration as the first count manager 1223a. Below, the first count manager 1223a will be described as an example. The first count manager 1223a may adjust a ratio of a count corresponding to the dynamic leakage current and a count corresponding to the static leakage current.

According to an embodiment, the AND gate AG may output the first block count signal BC1 by performing an AND operation on the active request ACT and the first block signal BLK1. The frequency divider 12231 may receive the first block count signal BC1 and may output a first weighted block count signal W_BC1. The first weighted block count signal W_BC1 may be a signal that is obtained by changing a frequency of the first block count signal BC1. The frequency divider 12231 may change the frequency of the first block count signal BC1 based on a weight WT. The weight WT may be determined based on an increase/decrease of the dynamic leakage current. As an example, when the influence of the dynamic leakage current increases compared to the static leakage current (e.g., when the temperature of the memory device 1200 decreases or when an active state of an adjacent memory cell is maintained during a given time or more (long-tRAS)), the memory device 1200 may increase the weight WT to increase the number of counts corresponding to (or associated with) the active request ACT. When the influence of the dynamic leakage current decreases compared to the static leakage current (e.g., when the temperature of the memory device 1200 increases), the memory device 1200 may decrease the weight WT to decrease the number of counts corresponding to (or associated with) the active request ACT.

According to an embodiment, the OR gate OG may output the first count signal CNT1 by performing an OR operation on the first weighted block count signal W_BC1 and the oscillation signal OSC. When the access to the first memory block 1211a is made, the first count signal CNT1 may increase the refresh count of the first refresh counter 1224a. Also, the first count signal CNT1 may increase the refresh count of the first refresh counter 1224a periodically depending on the oscillation signal OSC. The first count manager 1223a may adjust a weight of the number of counts corresponding to (or associated with) the active request ACT based on the first weighted block count signal W_BC1.

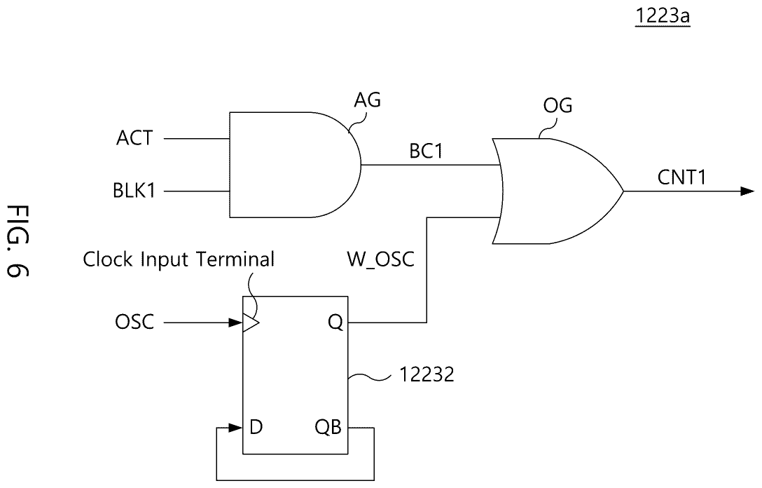

FIG. 6 is a diagram illustrating another example of a count manager of FIG. 3. Referring to FIGS. 3 and 6, the first count manager 1223a may include the AND gate AG, a D-flip-flop 12232, and the OR gate OG. Likewise, the remaining count managers 1223b, . . . , and 1223c may include the same configuration as the first count manager 1223a. Below, the first count manager 1223a will be described as an example. The first count manager 1223a may adjust a ratio of a count corresponding to the dynamic leakage current and a count corresponding to the static leakage current.

According to an embodiment, the AND gate AG may output the first block count signal BC1 by performing an AND operation on the active request ACT and the first block signal BLK1. The OR gate OG may output the first count signal CNT1 by performing an OR operation on the first block count signal BC1 and a weighted oscillation signal W_OSC. When the access to the first memory block 1211a is made, the first count signal CNT1 may increase the refresh count of the first refresh counter 1224a. Also, the first count signal CNT1 may increase the refresh count of the first refresh counter 1224a periodically depending on the weighted oscillation signal W_OSC.

According to an embodiment, the D-flip-flop 12232 may receive the oscillation signal OSC and may output the weighted oscillation signal W_OSC. For example, an output terminal “Q” of the D-flip-flop 12232 may output the weighted oscillation signal W_OSC. A signal of an inverting output terminal QB of the D-flip-flop 12232 may be input to an input terminal “D”. The oscillation signal OSC may be input to a clock input terminal. The D-flip-flop 12232 may decrease the frequency of the oscillation signal OSC to output the weighted oscillation signal W_OSC. As such, the number of counts corresponding to (or associated with) the static leakage current may be less applied to the first count signal CNT1. When the influence of the static leakage current decreases compared to the dynamic leakage current (e.g., when the temperature of the memory device 1200 decreases), the memory device 1200 may decrease the frequency of the oscillation signal OSC such that the number of counts associated with the static leakage current (e.g., the number of counts generated by the oscillator 1222) decreases.

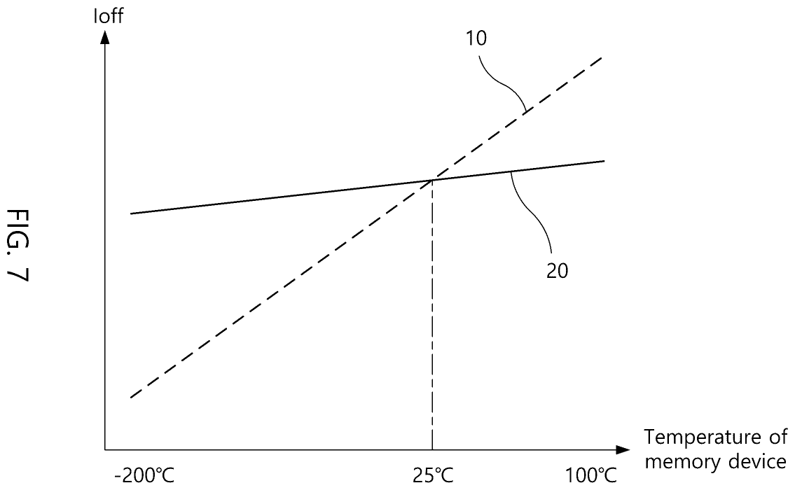

FIG. 7 is a graph illustrating a leakage current of a memory cell to a temperature of a memory device according to an embodiment. Referring to FIG. 7, a first graph 10 represents a static leakage current according to a characteristic of memory cells included in the memory device 1200 of the memory device 1200. A second graph 20 represents a dynamic leakage current (e.g., a row hammer leakage current) that is proportional to the number of times of access of an adjacent memory cell among the memory cells included in the memory device 1200. In FIG. 7, a vertical axis represents a leakage current Ioff, and a horizontal axis represents a temperature of the memory device 1200.

According to an embodiment, the first graph 10 shows how the static leakage current increases/decreases in proportion to the temperature of the memory device 1200. The second graph 20 shows that the dynamic leakage current is less variable than the static leakage current to the temperature of the memory device 1200. Accordingly, the memory device 1200 needs to perform the refresh operation in consideration of both the static leakage current and the dynamic leakage current. However, in the case where the number of times of refresh operation is determined in a state of independently considering the refresh operation for the static leakage current and the refresh operation for the dynamic leakage current, which overlap each other, the refresh operation may be excessively performed, thereby reducing the performance of operation of the memory device 1200.

As such, the memory device 1200 of the present invention may divide the memory banks 1210 into a plurality of memory blocks and may measure a refresh count for each memory block. When the access to each memory block is made, the memory device 1200 may increase the refresh count of each memory block in consideration of the dynamic leakage current. Also, the memory device 1200 may increase the refresh counts of all the memory blocks periodically in consideration of the static leakage current. The memory device 1200 may perform the refresh operation on a memory block whose refresh count reaches the refresh reference value. Accordingly, the memory device 1200 may perform the refresh operation in consideration of both the dynamic leakage current and the static leakage current. Also, the performance deterioration of the memory device 1200 may be reduced by performing the refresh operation based on the refresh count to which both the static leakage current and the dynamic leakage current are applied and preventing the refresh operation for the static leakage current and the refresh operation for the dynamic leakage current from overlapping each other.

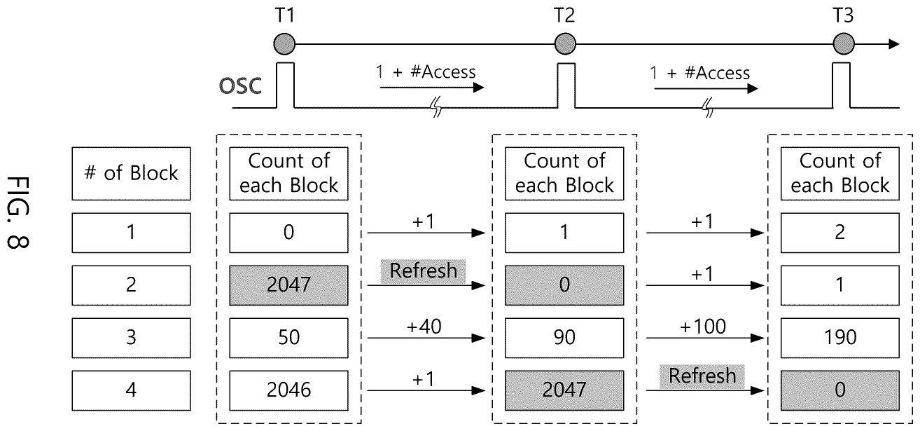

FIG. 8 is a diagram illustrating a refresh operation of a memory device of FIG. 3. Referring to FIG. 8, the memory device 1200 may include a memory bank that is composed of 4 memory blocks (e.g., Block #1, Block #2, Block #3, and Block #4) and may perform the refresh operation for each memory block. The oscillation circuit 1222 may generate the oscillation signal OSC having information of a specified period (e.g., 1 ms).

According to an embodiment, at a first time T1, the refresh count of the second memory block Block #2 may reach a specified refresh reference value (e.g., 2047), and the refresh manager 1225 may perform the refresh operation on the second memory block Block #2. Also, the refresh manager 1225 may initialize a second refresh counter (e.g., the second refresh counter 1224b of FIG. 3) corresponding to the second memory block Block #2.

According to an embodiment, in a time period from T1 to T2, the second refresh counter corresponding to the second memory block Block #2 may be initialized, and a first refresh counter (e.g., the first refresh counter 1224a of FIG. 3) corresponding to the first memory block Block #1, a third refresh counter corresponding to the third memory block Block #3, and a fourth refresh counter corresponding to the fourth memory block Block #4 may increase the refresh counts based on the oscillation signal OSC. Also, the third refresh counter may increase the refresh count (e.g., 39 times) based on the number of times #Access (e.g., 39 times) of access to the third memory block Block #3. That is, in the time period from T1 to T2, the third refresh counter may increase the refresh count (e.g., 40 times) including the number of times #Access (e.g., 39 times) of access to the third memory block Block #3 and the count (e.g., once) by the oscillation signal OSC.

According to an embodiment, at a second time T2, the refresh count of the fourth memory block Block #4 may reach the specified refresh reference value (e.g., 2047), and the refresh manager 1225 may perform the refresh operation on the fourth memory block Block #4. Also, the refresh manager 1225 may initialize the fourth refresh count corresponding to the fourth memory block Block #4.

According to an embodiment, in a time period from T2 to T3, the fourth refresh counter may be initialized, and the first refresh counter, the second refresh counter, and the third refresh counter may increase the refresh counts based on the oscillation signal OSC. Also, the third refresh counter may increase the refresh count (e.g., 99 times) based on the number of times #Access (e.g., 99 times) of access to the third memory block Block #3. That is, in the time period from T2 to T3, the third refresh counter may increase the refresh count (e.g., 100 times) including the number of times #Access (e.g., 99 times) of access to the third memory block Block #3 and the count (e.g., once) by the oscillation signal OSC.

According to an embodiment, the time period from T1 to T2 (or the time period from T2 to T3) may be changed depending on a weight. When the influence of the static leakage current decreases compared to the dynamic leakage current (e.g., when the temperature of the memory device 1200 decreases), the memory device 1200 may decrease the number of counts associated with the oscillation signal OSC (e.g., may decrease the frequency of the oscillation signal OSC). According to an embodiment, the time period from T1 to T2 (or the time period from T2 to T3) may be set to 1 ms. As another example, when the weight is applied, the time period from T1 to T2 (or the time period from T2 to T3) may be set to 10 ms, but not limited thereto.

According to an embodiment, the increment of the number of counts associated with the number of times of access to a memory block may be changed depending on a weight. For example, when the influence of the dynamic leakage current increases compared to the static leakage current (e.g., when the temperature of the memory device 1200 decreases or when an active state of an adjacent memory cell is maintained during a given time or more (long-tRAS)), the memory device 1200 may increase the number of counts corresponding to (or associated with) the active request ACT. Alternatively, when the influence of the dynamic leakage current decreases compared to the static leakage current (e.g., when the temperature of the memory device 1200 increases), the memory device 1200 may decrease the number of counts corresponding to (or associated with) the active request ACT.

As described above, the memory device 1200 of the present invention may divide a memory bank into memory blocks and may obtain the refresh count for each memory block. The refresh count may include both a count associated with the number of times of access to a memory block and a count periodically increasing based on a characteristic of a memory cell. The memory device 1200 may perform the refresh operation based on the above refresh count. The memory device 1200 may perform the refresh operation on a memory block whose refresh count reaches a refresh reference value. Also, the memory device 1200 may perform the refresh operation in consideration of both the dynamic leakage current and the static leakage current. Also, the performance deterioration of the memory device 1200 may be reduced by preventing the refresh operation for the static leakage current and the refresh operation for the dynamic leakage current from overlapping each other.

According to the present invention, the data loss may be prevented by performing the refresh operation in consideration of various events (e.g., a characteristic of a memory cell and an access history) causing the leakage current in a memory cell.

Also, according to the present invention, the performance of the memory device may be optimally maintained by preventing the refresh operation based on the number of times of access and the refresh operation based on a characteristic of a memory cell from overlapping each other.

While the present invention has been described with reference to embodiments thereof, it will be apparent to those of ordinary skill in the art that various changes and modifications may be made thereto without departing from the scope of the present disclosure as set forth in the following claims.

What is claimed is:

1. A memory device comprising:
a memory bank including a plurality of memory cells; and
a control logic configured to control a data input/output operation for the plurality of memory cells,
wherein the control logic is configured to:
partially measure a refresh count, which is associated with a number of occurrences of an event causing a leakage current in the plurality of memory cells; and
partially perform a refresh operation on the memory bank based on the refresh count.

2. The memory device of claim 1, wherein the event includes receiving an active request for activating a memory row included in a part of the memory bank.

3. The memory device of claim 1, wherein the event includes maintaining a part of the memory bank in an active state during at least a specified time.

4. The memory device of claim 1, wherein the event includes generating an oscillation signal by the control logic, and the oscillation signal includes information of a specified period.

5. The memory device of claim 1, wherein the control logic is configured to apply different weights to the event depending on a cause of the event.

6. A memory device comprising:
a memory bank including a plurality of memory blocks that includes a plurality of memory cells; and
a control logic configured to control a data input/output operation for the plurality of memory cells,
wherein the control logic is configured to:
measure a refresh count that is calculated based on a first count and a second count; and
perform a refresh operation for a memory block from among the plurality of memory blocks, based on the refresh count.

7. The memory device of claim 6, wherein the first count is determined based on an access history of the memory block, and the second count is determined based on a characteristic of the plurality of memory cells.

8. The memory device of claim 7, wherein the control logic is configured to apply different weights to the first count and the second count.

9. The memory device of claim 7, wherein the control logic includes:
a block decoder configured to output a block signal for selecting the memory block based on an active request and a row address received from a controller;
an oscillator configured to generate an oscillation signal pulsing with a specified period;
a count manager configured to output a count signal for the memory block, based on the active request, the block signal, and the oscillation signal;
a refresh counter configured to store the refresh count corresponding to the memory block and increasing by one depending on the count signal; and
a refresh manager configured to output a refresh signal based on the refresh count such that the refresh operation is performed for the memory block.

10. The memory device of claim 9, wherein the count manager includes:
an AND gate configured to output a block count signal by performing an AND operation on the active request and the block signal; and
an OR gate configured to output the count signal by performing an OR operation on the block count signal and the oscillation signal.

11. The memory device of claim 9, wherein the count manager includes:
an AND gate configured to output a block count signal by performing an AND operation on the active request and the block signal;
a frequency divider configured to receive the block count signal and configured to output a weighted block count signal by changing a frequency of the block count signal based on a specified weight; and
an OR gate configured to output the count signal by performing an OR operation on the weighted block count signal and the oscillation signal.

12. The memory device of claim 9, wherein the count manager includes:
an AND gate configured to output a block count signal by performing an AND operation on the active request and the block signal;
a D-flip-flop configured to output a weighted oscillation signal by decreasing a frequency of the oscillation signal; and
an OR gate configured to output the count signal by performing an OR operation on the block count signal and the weighted oscillation signal.

13. The memory device of claim 9, wherein the refresh manager is configured to:
receive count status information corresponding to the memory block from the refresh counter; and
output the refresh signal for the memory block when the refresh count reaches a refresh reference value.

14. The memory device of claim 9, wherein the refresh manager is configured to send a reset signal for initializing the refresh count to the refresh counter in which the refresh count reaches a refresh reference value.

15. The memory device of claim 6, wherein the memory block includes a group of memory rows identified by a sense amplifier.

16. The memory device of claim 6, wherein the memory block includes a group of memory rows identified by a plurality of sense amplifiers.

17. A memory device comprising:
a memory bank including a plurality of memory blocks that includes a plurality of memory cells; and
a control logic configured to control a data input/output operation for the plurality of memory cells,
wherein the control logic is configured to:
generate a block signal for selecting a first memory block from among the plurality of memory blocks based on an active request and a row address received from a controller;
when the active request and the block signal are activated, increase a first count for the first memory block, or when an oscillation signal to be periodically generated is activated, increase a second count for each of the plurality of memory blocks; and
perform a refresh operation on the first memory block, based on a refresh count that is calculated based on the first and second counts.

18. The memory device of claim 17, wherein the control logic is configured to perform the refresh operation on a second memory block, in which the refresh count reaches a refresh reference value, from among the plurality of memory blocks.

19. The memory device of claim 18, wherein the control logic is configured to initialize the refresh count of the second memory block when the refresh operation is performed.

20. The memory device of claim 17, wherein, based on a refresh command received from the controller or generated by the control logic, the control logic is configured to perform the refresh operation on a third memory block, in which the refresh count reaches a refresh reference value, from among the plurality of memory blocks.
